(19) United States
(12) Patent Application Publication
(10) Pub. No.: US 2011/0181341 A1
(43) Pub. Date: Jul. 28, 2011

(54) PUSH-PULL DRIVER CIRCUIT

(75) Inventors: Kenichi ISHIBASHI, Osaka (JP); Tetsu Nagano, Osaka (JP); Daijiro Arisawa, Kyoto (JP)

(73) Assignee: Panasonic Corporation, Osaka (JP)

(21) Appl. No.: 13/079,507

(22) Filed: Apr. 4, 2011

Related U.S. Application Data
(63) Continuation of application No. PCT/JP2010/004487, filed on Jul. 9, 2010.

(30) Foreign Application Priority Data
Nov. 25, 2009 (JP) 2009-267492

(51) Int. Cl. H03L 5/00

(52) U.S. Cl. 327/333

(57) ABSTRACT

A push-pull driver circuit includes a control circuit which controls switching operations of a plurality of high-side transistors, a level-shift circuit which shifts a control signal, output by the control circuit when the control circuit performs turn-off control on the plurality of transistors, to a first voltage by which the plurality of transistors are turned off, and which inputs the shifted signal to a gate of one of the plurality of transistors, and a conduction-state selection circuit which, if an output of the level-shift circuit is the first voltage, inputs the output to gates of the rest of the transistors, and otherwise, according to the control by the control circuit, sets each of gate inputs of the rest of the transistors to either a high-impedance state or a second voltage by which the plurality of transistors are turned on.

### CROSS-REFERENCE TO RELATED APPLICATION

This is a continuation of PCT International Application PCT/JP2010/004487 filed on Jul. 9, 2010, which claims priority to Japanese Patent Application No. 2009-267492 filed on Nov. 25, 2009. The disclosures of these applications including the specifications, the drawings, and the claims are hereby incorporated by reference in its entirety.

### BACKGROUND

The present disclosure relates to push-pull driver circuits, and more particularly to push-pull driver circuits providing higher-voltage outputs suitable for driving plasma display panels (PDPs) etc.

Generally, a push-pull driver circuit turns, on and off alternately, a high-side p-channel transistor and a low-side n-channel transistor coupled in series between a supply voltage and ground to drive an output load connected to a connection point of these transistors. In a push-pull driver circuit providing a higher-voltage output for driving a PDP etc., a higher voltage is applied to the source of the high-side transistor. Turn-off control of such a high-side transistor cannot be performed by a control voltage of a more general circuit. Accordingly, a push-pull driver circuit providing a higher-voltage output performs turn-off control of a high-side transistor by level-shifting of the control voltage by a level-shift circuit.

It is preferable that the drive capability of a push-pull driver circuit be changed according to the amount of the output load. Therefore, a plurality of high-side transistors are coupled in parallel, and turn-on control is independently performed on each of the high-side transistors to allow the drive capability of a push-pull driver circuit to be switchable (see, e.g., Japanese Patent Publication No. 2008-003567).

If a push-pull driver circuit providing a higher-voltage output includes a plurality of high-side transistors, and turn-on control can be independently performed on each of the high-side transistors, then a level-shift circuit is required to be provided for each high-side transistor, thus the number of level-shift circuits is increased. In addition, if a push-pull driver circuit supports multichannel operation such as a driver integrated circuit (IC) of a PDP, a vast number of level-shift circuits are additionally required for an entire IC.

FIG. 8 illustrates an example configuration of a level-shift circuit. A typical level-shift circuit includes four withstanding transistors, and shifts the high logic level of an input signal from a control voltage VDD to a higher voltage VDDH. Such a level-shift circuit requiring as many as four withstanding transistors each having a larger size than a general transistor is a large-size high-cost circuit element. Therefore, providing a large number of such level-shift circuits leads to an increase in chip area and cost.

### SUMMARY

A push-pull driver circuit according to the present disclosure may be advantageous when a higher-voltage output is required without using a large number of level-shift circuits.

A push-pull driver circuit according to one embodiment having a plurality of transistors coupled in parallel either in a high side or in a low side includes a control circuit configured to control switching operations of the plurality of transistors, a level-shift circuit configured to shift a control signal, output by the control circuit when the control circuit performs turn-off control on the plurality of transistors, to a first voltage by which the plurality of transistors are turned off, and to input the shifted signal to a gate of one of the plurality of transistors, and a conduction-state selection circuit configured to, if an output of the level-shift circuit is the first voltage, input the output to gates of the rest of the transistors, and otherwise, according to the control by the control circuit, set each of gate inputs of the rest of the transistors to either a high-impedance state or a second voltage by which the plurality of transistors are turned on. The push-pull driver circuit may include a clamp circuit configured to clamp each of gate voltages of the rest of the transistors to the first voltage.

The above configuration ensures independence of turn-on control of the plurality of transistors, and at the same time allows the number of level-shift circuits including a large number of withstanding transistors to be reduced to one. Moreover, providing a clamp circuit allows the gate breakdown voltage requirement required of the rest of the transistors to be relaxed.

### BRIEF DESCRIPTION OF THE DRAWINGS

FIG. 1 is a configuration diagram of a push-pull driver circuit according to the first embodiment.

FIG. 2 is a diagram illustrating an example configuration of the conduction-state selection circuit and the clamp circuit.

FIG. 3 is a graph showing a relationship between an output voltage of the push-pull driver circuit of FIG. 1 and the gate voltages of respective transistors.

FIG. 4 is a configuration diagram of a push-pull driver circuit according to a variation of the first embodiment.

FIG. 5 is a configuration diagram of a push-pull driver circuit according to the second embodiment.

FIG. 6 is a graph showing a transition process of the output voltage with respect to the number of high-side transistors which are in an ON state.

FIG. 7 is a configuration diagram of a push-pull driver circuit according to a variation of the second embodiment.

FIG. 8 is a diagram illustrating an example configuration of a level-shift circuit.

### DETAILED DESCRIPTION

### First Embodiment

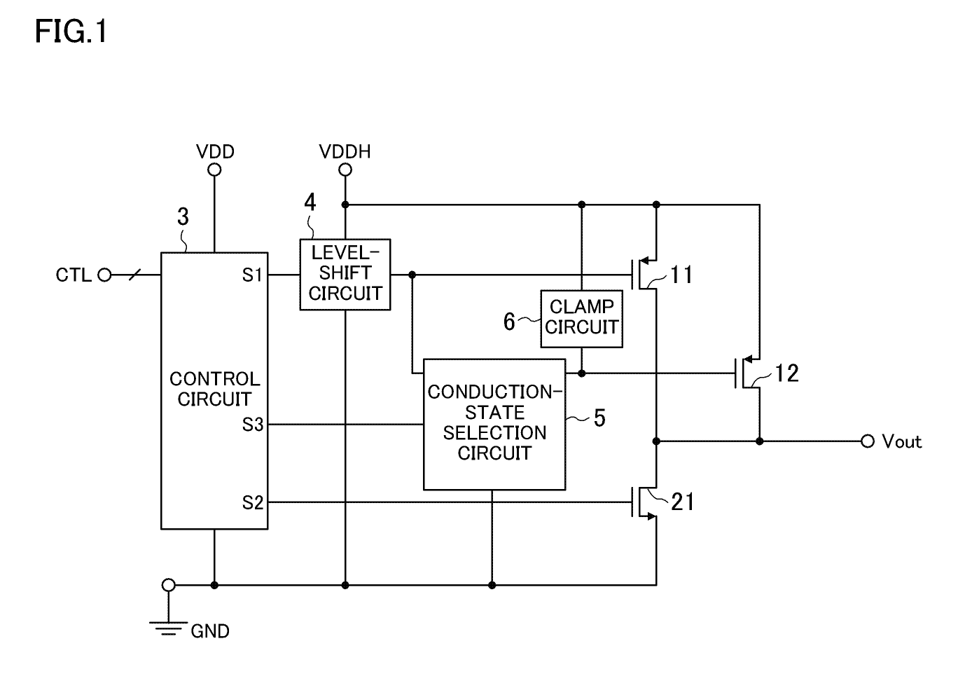

FIG. 1 illustrates a configuration of a push-pull driver circuit according to the first embodiment. A higher voltage VDDH is applied to the sources of two high-side p-channel transistors 11 and 12 coupled in parallel. A ground voltage GND is applied to the source of a low-side n-channel transistor 21. An output load (not shown) is driven at a voltage Vout at the connection point between the high-side transistors 11 and 12 and the low-side transistor 21.

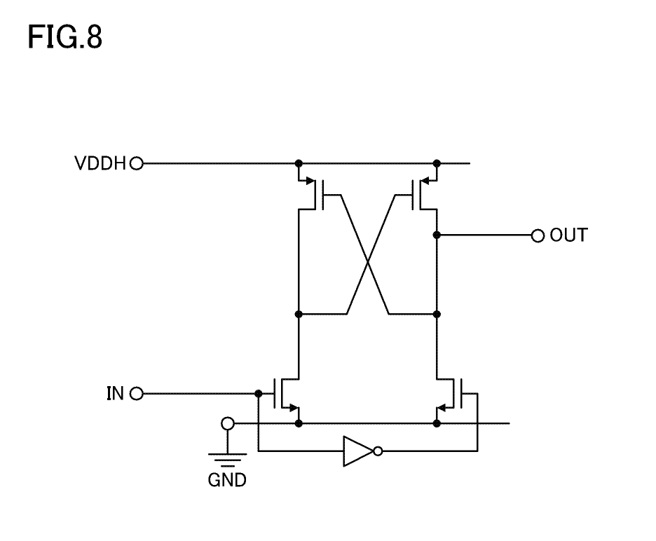

A control circuit 3 operates by being supplied a control voltage VDD, and outputs control signals S1, S2, and S3 according to a control signal CTL input from a central processing unit (CPU) (not shown) etc. to control switching operations of the transistors 11, 12, and 21. A level-shift circuit 4 shifts the high logic level of the control signal S1 from the control voltage VDD to the higher voltage VDDH. The detailed configuration of the level-shift circuit 4 is shown in FIG. 8. The transistor 11 is controlled by an output of the level-shift circuit 4. That is, when the control signal S1 is at a high logic level, the higher voltage VDDH is applied to the gate of the transistor 11, and the transistor 11 is turned off, while when the control signal S1 is at a low logic level, the ground voltage GND is applied to the gate, and the transistor 11 is turned on. The transistor 21 is controlled directly by the control signal S2. Note that the high logic level output of the level-shift circuit 4 is not limited to the higher voltage VDDH, but may be any voltage that can turn off the transistors 11 and 12.

A conduction-state selection circuit 5 inputs the higher voltage VDDH to the gate of the transistor 12 when the higher voltage VDDH is output from the level-shift circuit 4. That is, when the control signal S1 is at a high logic level, the higher voltage VDDH is applied to the gate of the transistor 12, and the transistor 12 is turned off. Meanwhile, when the higher voltage VDDH is not output from the level-shift circuit 4, the conduction-state selection circuit 5 sets the gate input of the transistor 12 to either a high-impedance state or the ground voltage GND according to the logic level of the control signal S3. For example, if the control signal S1 is at a low logic level and the control signal S3 is at a low logic level, then the gate input of the transistor 12 is set to a high-impedance state. In this condition, the gate voltage is maintained at the higher voltage VDDH by a gate-drain parasitic capacitance (not shown), thereby causing the transistor 12 to be maintained in an OFF state. Meanwhile, if, for example, the control signal S1 is at a low logic level and the control signal S3 is at a high logic level, then the ground voltage GND is applied to the gate, and the transistor 12 is turned on. Note that the voltage applied by the conduction-state selection circuit 5 to the gate of the transistor 12 is not limited to the ground voltage GND, but may be any voltage that can turn on the transistor 12.

A clamp circuit 6 is inserted between the gate of the transistor 12 and the higher voltage VDDH. The clamp circuit 6 clamps the gate voltage of the transistor 12 to the higher voltage VDDH. Note that the clamp circuit 6 may be omitted if the gate breakdown voltage of the transistor 12 is greater than or equal to twice the higher voltage VDDH.

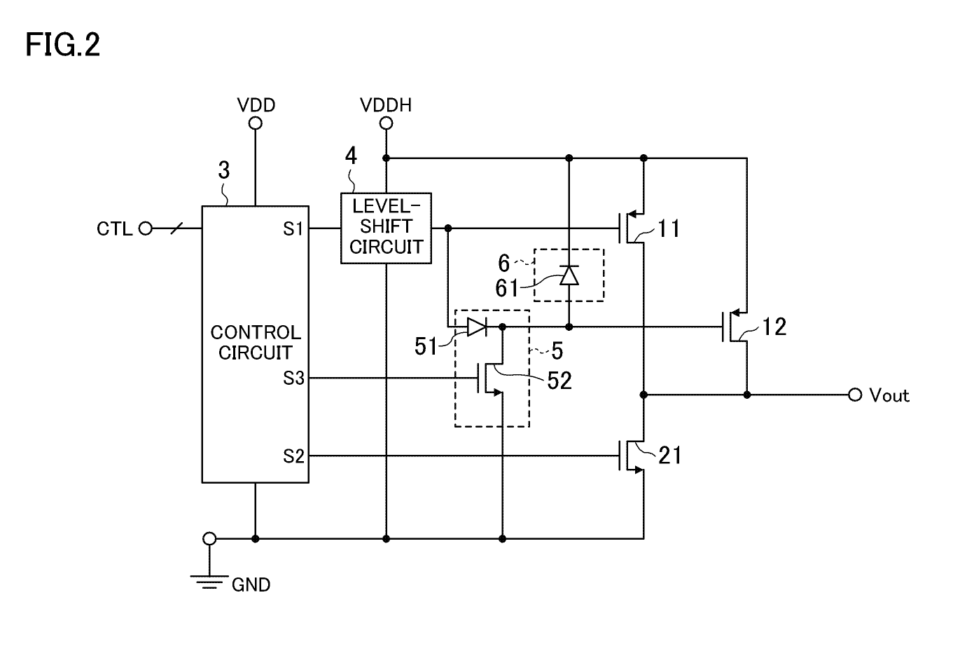

FIG. 2 illustrates an example configuration of the conduction-state selection circuit 5 and the clamp circuit 6. The conduction-state selection circuit 5 can be implemented with a diode 51 whose anode is coupled to the output of the level-shift circuit 4, and whose cathode is coupled to the gate of the transistor 12, and an n-channel transistor 52, coupled between the gate of the transistor 12 and ground, on which switching control is performed by the control signal S3. The clamp circuit 6 can be implemented with a diode 61 whose anode is coupled to the gate of the transistor 12, and whose cathode is coupled to the higher voltage VDDH. Note that the conduction-state selection circuit 5 and the clamp circuit 6 may be implemented in various manners other than that described above.

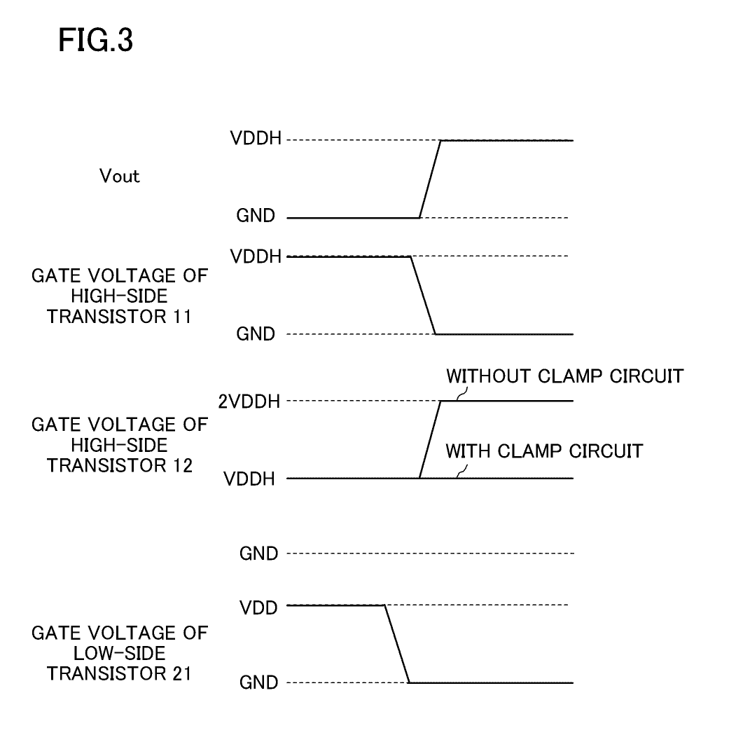

FIG. 3 shows a relationship between the voltage Vout and the gate voltages of the respective transistors 11, 12, and 21 when only the transistor 21 is turned on and when only the transistor 11 is turned on thereafter. In an initial state, the control signals S1 and S2 are each at a high logic level, and the control signal S3 is at a low logic level, during which the higher voltage VDDH is applied to each of the gates of the transistors 11 and 12, and the transistors 11 and 12 are turned off; and the control voltage VDD is applied to the gate of the transistor 21, and the transistor 21 is turned on. Accordingly, the push-pull driver circuit outputs the ground voltage GND. Thereafter, when the control signals S1 and S2 transition to a low logic level, the ground voltage GND is applied to the gate of the transistor 11, and the transistor 11 is turned on; and the ground voltage GND is applied to the gate of the transistor 21, and the transistor 21 is turned off. Meanwhile, since the control signal S3 remains at a low logic level, the gate input of the transistor 12 is in a high-impedance state, and thus the gate voltage is maintained at the higher voltage VDDH if the clamp circuit 6 is provided, while the gate voltage increases to twice the higher voltage VDDH if the clamp circuit 6 is not provided. In either case, the gate voltage of the transistor 12 is maintained at a voltage high enough to allow the transistor 12 to be maintained in an OFF state.

Although not shown, when the control signal S3 thereafter transitions to a high logic level, the ground voltage GND is applied to the gate of the transistor 12, and the transistor 12 is turned on. Thus, turn-off control can be performed independently on the transistors 11 and 12. For example, assuming that the ratio of current capabilities of the transistors 11 and 12 is 1:9, turn-on control may be performed on both the transistors 11 and 12 for a normal case where only a single channel is operated in a multiple-channel push-pull driver circuit, while turn-on control may be performed on only the transistor 11 if no quick response is required such as a case where all the channels are operated at one time in a multiple-channel push-pull driver circuit. This allows the source current capability to be reduced to 1/10, and thus unwanted radiation noise and power consumption to be reduced.

Thus, according to this embodiment, the push-pull driver circuit providing higher-voltage outputs, having the two high-side transistors 11 and 12 on which independent turn-on control can be performed, needs to have only one level-shift circuit. This allows the required number of withstanding transistors to be reduced, and thus size and cost reduction of a push-pull driver circuit to be achieved. Note that even though the example configuration shown in FIG. 2 requires one withstanding transistor in the conduction-state selection circuit 5, the number of withstanding transistors can be reduced by three compared to when a level-shift circuit is additionally provided. As such, if a multiple-channel push-pull driver circuit is used, the number of withstanding transistors can be further reduced, and thus effects on size and cost reduction are significant.

(Variation)

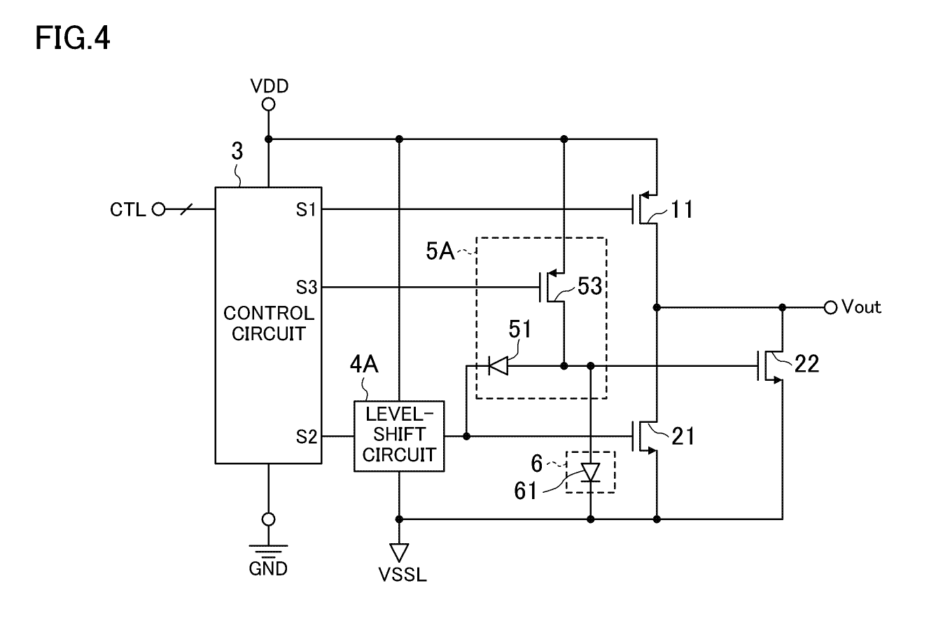

A push-pull driver circuit providing a negative higher-voltage output can be implemented by an appropriate variation of the push-pull driver circuit according to this embodiment. FIG. 4 illustrates a configuration of a push-pull driver circuit according to a variation of this embodiment. The control voltage VDD is applied to the source of the high-side p-channel transistor 11. A negative higher voltage VSSL is applied to the sources of two low-side n-channel transistors 21 and 22 coupled in parallel. An output load (not shown) is driven at a voltage Vout at the connection point between the high-side transistor 11 and the low-side transistors 21 and 22.

The control circuit 3 operates by being supplied the control voltage VDD, and outputs control signals S1, S2, and S3 according to the control signal CTL input from a CPU (not shown) etc. to control switching operations of the transistors 11, 21, and 22.

A level-shift circuit 4A shifts the low logic level of the control signal S2 from the ground voltage GND to the negative higher voltage VSSL. The transistor 21 is controlled by an output of the level-shift circuit 4A. That is, when the control signal S2 is at a low logic level, the negative higher voltage VSSL is applied to the gate of the transistor 21, and the transistor 21 is turned off, while when the control signal S2 is at a high logic level, the control voltage VDD is applied to the gate, and the transistor 21 is turned on. The transistor 11 is controlled directly by the control signal S1. Note that the low logic level output of the level-shift circuit 4A is not limited to the negative higher voltage VSSL, but may be any voltage that can turn off the transistors 21 and 22.

A conduction-state selection circuit 5A can be implemented with a diode 51 whose anode is coupled to the gate of the transistor 22, and whose cathode is coupled to the output of the level-shift circuit 4A, and a p-channel transistor 53, coupled between the gate of the transistor 22 and the control voltage VDD, on which switching control is performed by the control signal S3. The conduction-state selection circuit 5A inputs the negative higher voltage VSSL to the gate of the transistor 22 when the negative higher voltage VSSL is output from the level-shift circuit 4A. That is, when the control signal S2 is at a low logic level, the negative higher voltage VSSL is applied to the gate of the transistor 22, and the transistor 22 is turned off. Meanwhile, when the negative higher voltage VSSL is not output from the level-shift circuit 4A, the conduction-state selection circuit 5A sets the gate input of the transistor 22 to either a high-impedance state or the control voltage VDD according to the logic level of the control signal S3. For example, if the control signal S2 is at a high logic level and the control signal S3 is at a high logic level, then the gate input of the transistor 22 is set to a high-impedance state. In this condition, the gate voltage is maintained at the negative higher voltage VSSL by a gate-drain parasitic capacitance (not shown), thereby causing the transistor 22 to be maintained in an OFF state. Meanwhile, if, for example, the control signal S2 is at a high logic level and the control signal S3 is at a low logic level, then the control voltage VDD is applied to the gate, and the transistor 22 is turned on. Note that the voltage applied by the conduction-state selection circuit 5A to the gate of the transistor 22 is not limited to the control voltage VDD, but may be any voltage that can turn on the transistor 22.

The clamp circuit 6 is inserted between the gate of the transistor 22 and the negative higher voltage VSSL, and clamps the gate voltage of the transistor 22 to the negative higher voltage VSSL. The clamp circuit 6 can be implemented with a diode 61 whose anode is coupled to the gate of the transistor 22, and whose cathode is coupled to the negative higher voltage VSSL. Note that the clamp circuit 6 may be omitted if the gate breakdown voltage of the transistor 22 is greater than or equal to twice the negative higher voltage VSSL.

### Second Embodiment

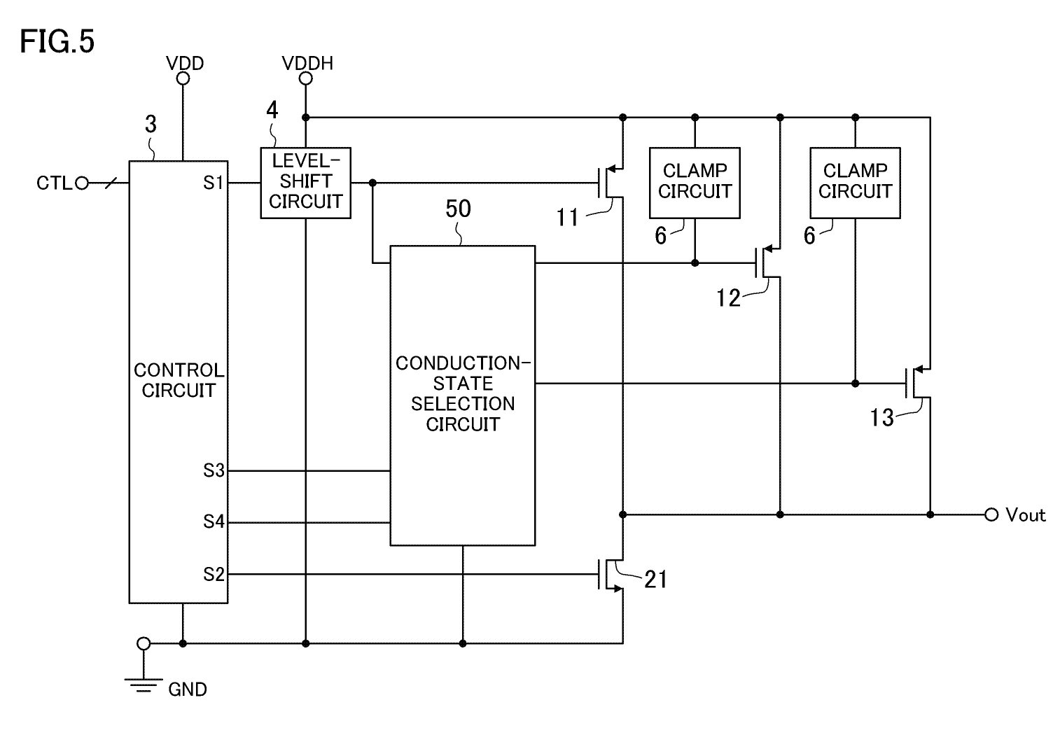

FIG. 5 illustrates a configuration of a push-pull driver circuit according to the second embodiment. The push-pull driver circuit according to this embodiment includes more high-side transistors than the push-pull driver circuit according to the first embodiment. The difference from the first embodiment will be described below.

A high-side p-channel transistor 13 is coupled in parallel to the transistors 11 and 12. An additional clamp circuit 6 is inserted between the gate of the transistor 13 and the higher voltage VDDH. This clamp circuit 6 clamps the gate voltage of the transistor 13 to the higher voltage VDDH. Note that this clamp circuit 6 may be omitted if the gate breakdown voltage of the transistor 13 is greater than or equal to twice the higher voltage VDDH.

A conduction-state selection circuit 50 inputs the higher voltage VDDH to the gates of the transistors 12 and 13 when the higher voltage VDDH is output from the level-shift circuit 4. That is, when the control signal S1 is at a high logic level, the higher voltage VDDH is applied to the gates, and the transistors 12 and 13 are turned off. Meanwhile, when the higher voltage VDDH is not output from the level-shift circuit 4, the conduction-state selection circuit 50 sets each of the gate inputs of the transistors 12 and 13 independently to either a high-impedance state or the ground voltage GND according to the logic levels of the control signal S3 and a control signal S4. For example, if the control signal S1 is at a low logic level and the control signal S4 is at a low logic level, then the gate input of the transistor 13 is set to a high-impedance state. In this condition, the gate voltage is maintained at the higher voltage VDDH by a gate-drain parasitic capacitance (not shown), thereby causing the transistor 13 to be maintained in an OFF state. Meanwhile, if, for example, the control signal S1 is at a low logic level and the control signal S4 is at a high logic level, then the ground voltage GND is applied to the gate, and the transistor 13 is turned on. The conduction-state selection circuit 50 can be implemented by a combination of two of the conduction-state selection circuits 5 shown in FIG. 2.

Turn-on control can be performed independently on the transistors 11, 12 and 13. Accordingly, it may be appropriate to switch as appropriate the drive capability of the push-pull driver circuit such that turn-on control is performed on three of the transistors when the unshown output load is heavy, on two of the transistors when the output load is moderate, or on one of the transistors when the output load is low.

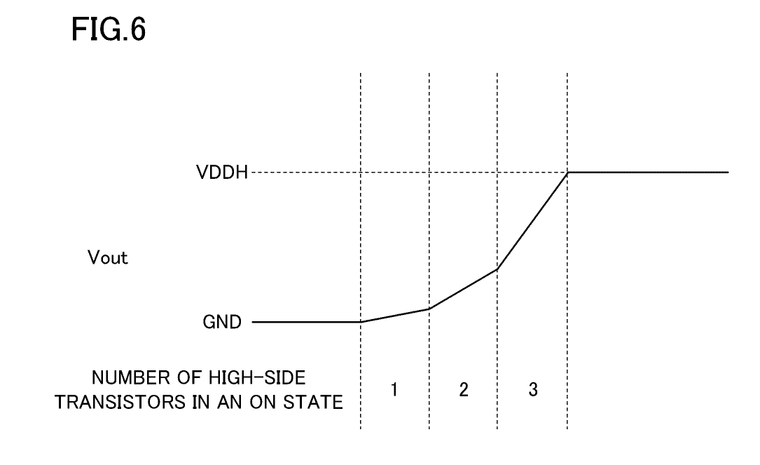

Moreover, when the output load increases, it may be appropriate to perform turn-on control on the transistors 11, 12 and 13 sequentially, instead of performing all at once. FIG. 6 shows a transition process of the voltage Vout with respect to the number of transistors 11, 12, and 13 which are in an ON state. If a heavy-load condition is indicated by the control signal CTL, the control circuit 3 performs turn-on control sequentially on the transistors 11, 12, and 13. This allows the slew rate of the voltage Vout to be gradually increased and prevents a rapid rise of the voltage Vout, thereby reduces unwanted radiation noise.

(Variation)

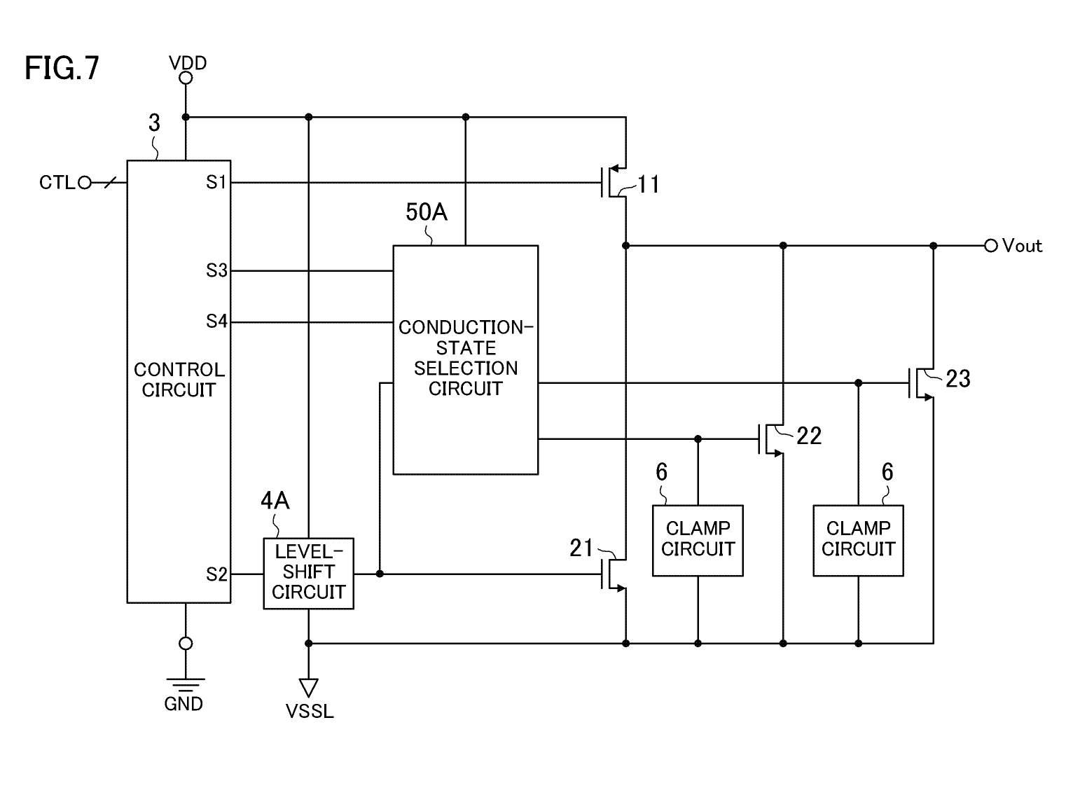

A push-pull driver circuit providing a negative higher-voltage output can be implemented by an appropriate variation of the push-pull driver circuit according to this embodiment. FIG. 7 illustrates a configuration of a push-pull driver circuit according to a variation of the second embodiment. The control voltage VDD is applied to the source of the high-side p-channel transistor 11. A negative higher voltage VSSL is applied to the sources of three low-side n-channel transistors 21, 22, and 23 coupled in parallel. An output load (not shown) is driven at a voltage Vout at the connection point between the high-side transistor 11 and the low-side transistors 21, 22, and 23.

A conduction-state selection circuit 50A inputs the negative higher voltage VSSL to the gates of the transistors 22 and 23 when the negative higher voltage VSSL is output from a level-shift circuit 4A. That is, when the control signal S2 is at a low logic level, the negative higher voltage VSSL is applied to the gates, and the transistors 22 and 23 are turned off. Meanwhile, when the negative higher voltage VSSL is not output from the level-shift circuit 4A, the conduction-state selection circuit 50A sets each of the gate inputs of the transistors 22 and 23 independently to either a high-impedance state or the control voltage VDD according to the logic levels of the control signal S3 and a control signal S4. For example, if the control signal S2 is at a low logic level and the control signal S4 is at a high logic level, then the gate input of the transistor 23 is set to a high-impedance state. In this condition, the gate voltage is maintained at the negative higher voltage VSSL by a gate-drain parasitic capacitance (not shown), thereby causing the transistor 23 to be maintained in an OFF state. Meanwhile, if, for example, the control signal S2 is at a low logic level and the control signal S4 is at a low logic level, then the control voltage VDD is applied to the gate, and the transistor 23 is turned on. The conduction-state selection circuit 50A can be implemented by a combination of two of the conduction-state selection circuits 5A shown in FIG. 4.

Although this embodiment and the variation thereof assume that the number of high-side or low-side transistors is three, more than three transistors may be used.

What is claimed is:

1. A push-pull driver circuit having a plurality of transistors coupled in parallel either in a high side or in a low side, comprising:
a control circuit configured to control switching operations of the plurality of transistors;
a level-shift circuit configured to shift a control signal, output by the control circuit when the control circuit performs turn-off control on the plurality of transistors, to a first voltage by which the plurality of transistors are turned off, and to input the shifted signal to a gate of one of the plurality of transistors; and
a conduction-state selection circuit configured to, if an output of the level-shift circuit is the first voltage, input the output to gates of the rest of the transistors, and otherwise, according to the control by the control circuit, set each of gate inputs of the rest of the transistors to either a high-impedance state or a second voltage by which the plurality of transistors are turned on.

2. The push-pull driver circuit of claim 1, further comprising:
a clamp circuit configured to clamp each of gate voltages of the rest of the transistors to the first voltage.

3. The push-pull driver circuit of claim 1, wherein
the control circuit performs turn-on control sequentially on the plurality of transistors.

4. The push-pull driver circuit of claim 1, wherein
the conduction-state selection circuit includes
a diode coupled between the output of the level-shift circuit and each of the gates of the rest of the transistors, and
a transistor, coupled between each of the gates of the rest of the transistors and the second voltage, on which switching control is performed by the control circuit.

5. The push-pull driver circuit of claim 1, wherein
the first voltage is a source voltage of the plurality of transistors.

6. The push-pull driver circuit of claim 1, wherein
the second voltage is a source voltage of a transistor, provided in an opposite side from the high or the low side, coupled in series to the plurality of transistors.
